(19) United States
(12) Patent Application Publication
(10) Pub. No.: US 2023/0406732 A1
(43) Pub. Date: Dec. 21, 2023

(54) A DIAMOND ASSEMBLY

(71) Applicant: Element Six Technologies Limited, Didcot, Oxfordshire (GB)

(72) Inventors: Julian James Sargood Ellis, Didcot (GB); Timothy Peter Mollart, Didcot (GB); Hossein Zarrin, Santa Clara, CA (US); Daniel James Twitchen, Didcot (GB)

(73) Assignee: Element Six Technologies Limited, Didcot, Oxfordshire (GB)

(21) Appl. No.: 18/247,680

(22) PCT Filed: Nov. 12, 2021
(86) PCT No.: PCT/EP2021/081488

§ 371 Date: Apr. 3, 2023

Related U.S. Application Data
(60) Provisional application No. 63/112,684, filed on Nov. 12, 2020.

(30) Foreign Application Priority Data
Nov. 26, 2020 (GB) 2018616.9

(51) Int. Cl. C02F 1/461; B32B 7/12; B32B 9/00; B32B 9/04; B32B 15/092; B32B 27/38; B32B 37/06; B32B 37/10; B32B 37/12; B32B 37/18; C09J 5/06; C09J 163/00; C09J 9/02

(52) U.S. Cl. CPC C02F 1/46109; B32B 7/12; B32B 9/007; B32B 9/041; B32B 9/045; B32B 15/092; B32B 27/38; B32B 37/06; B32B 37/10; B32B 37/12; B32B 37/18; B32B 37/182; C09J 5/06; C09J 163/00; C09J 9/02; C02F 2001/46147; B32B 2307/202; B32B 2307/7376; B32B 2309/02; B32B 2309/12; B32B 2313/04; B32B 2363/00; B32B 2457/00; C09J 2203/326; C09J 2463/00

(57) ABSTRACT

A bonded diamond assembly and a method of forming the assembly. The assembly comprises a polycrystalline diamond wafer having a largest linear dimension of between 25 mm and 200 mm, a substrate and a bonding layer located between the diamond and the substrate and bonding them together. The bonding layer, when inspected using ultrasound using a resolution of 50 μm, a focal length selected to inspect the bonding layer, and frequencies of 100 MHz and 30 MHz, comprises low numbers of voids extending either across the thickness of the bonding layer and low numbers of voids that do not extend across the thickness of the bonding layer.

### FIELD

The invention relates to diamond assemblies manufactured from diamond bonded to a substrate, methods for making such assemblies, and apparatus for making such assemblies.

### BACKGROUND

Diamond is well known for its wide ranging and extreme properties. For example, its exceptional thermal conductivity makes it suitable for use as a heat spreader in thermal applications. By doping diamond with boron, it can be made into an electrical conductor. Un-doped diamond on the other hand is a dielectric and could potentially be used in capacitor applications. Many of these types of application of diamond require it to be bonded to a substrate, for example a metal substrate to allow an electrical connection to be made.

To discuss Boron doped diamond (BDD) in more detail, this material is useful in electrochemical generation of oxidizing species by virtue of its chemical inertness and wide potential window. The use of solid and coated BDD electrodes in electrochemical systems has been described in, e.g. EP0659691 and U.S. Pat. No. 5,399,247. These patents describe the use of conductive diamond electrodes in electrochemical cells.

Polycrystalline diamond is typically manufactured using a chemical vapour deposition (CVD) process. CVD manufacture of diamond requires considerable capital expenditure and consumption of electricity in proportion to the area being coated. Thicker layers are therefore proportionately more expensive to produce than thinner layers. It is therefore critical in a commercially viable process to ensure that post-growth procedures, such as bonding the diamond to a substrate, do not damage the diamond. For electrochemical cell applications, it is a requirement of a cost-effective BDD electrode electrochemical cell to maximize the working surface area of the BDD relative to its volume.

CVD diamond can be grown directly onto a refractory metal substrate, but during growth stresses can build up owing a mis-match in the thermal expansion coefficient of the diamond and the metal substrate. These stresses can cause diamond to delaminate during the growth process, which ruins the growth run and wastes the material already grown. This can be mitigated to a certain extent by limiting the diamond layer thickness, growing more slowly, or at lower power densities, but then the process becomes commercially less attractive. Furthermore, the substrate is usually relative thick (of the order of millimetres), which introduces a significant cost for the substrate for a BDD electrode.

There is therefore a need to bond large area polycrystalline diamond to a large contact substrate. However, the larger the area of the bonded area, the greater the likelihood of voids and other defects that can degrade performance of the electrode. Voids may be caused by uneven application of bonding material, poor adhesive flow of bonding material and a flatness mismatch between the diamond and the substrate. This is problematic when using bonding materials such as viscous electrically conducting epoxy paste.

Voids in the bonding layer between the polycrystalline diamond and the substrate can lead to cracking and delamination of the diamond from the substrate. Furthermore, voids between the diamond and the substrate can reduce the power density that the combined diamond/substrate can hold when used as an electrode.

Furthermore, backing substrates and diamond wafers can have some degree of bowing across their largest area, which can also be a source of poor bonding and voids. The larger the area, the greater the likelihood of bowing leading to poor bonding between the diamond and the substrate.

In electrode applications, it is known to address some of these problems by using freestanding BDD with no substrate, as they are not prone to failure by delamination or erosion of the BDD layer and oxidation of the substrate. However, while freestanding BDD electrodes are suitable for bipolar electrodes between an anode and the cathode. The term “bipolar electrode” as used herein refers to an electrode which, when placed between an anode and a cathode across which a potential is applied, will behave as both an anode and cathode. A bipolar electrode therefore has two major working surfaces in contact with the electrolyte. Furthermore, a bipolar electrode does not require a separate electrical connection, although one or more may be provided for monitoring purposes, for example. However, the anode and the cathode still require a separate electrical connection and the most convenient way to achieve this is to affix the diamond electrode to an electrically conductive substrate.

For non-electrode applications, it should be noted that non-electrically conductive diamond can be bonded to a substrate, for example in uses such as heat spreaders. Voids also have a deleterious effect where there is no direct thermal contact between the diamond and the substrate, and gives rise to problems with stress caused by a thermal mismatch between the diamond and the substrate.

### SUMMARY

It is an object to provide an improved diamond assembly that allows larger areas of diamond to be bonded to a substrate, with low thermal barrier resistance and low electrical resistivity while retaining an acceptable amount of voids and particulate impurities in the bonding layer.

According to a first aspect, there is provided a bonded diamond assembly comprising a polycrystalline diamond wafer having a largest linear dimension of between 25 mm and 200 mm, a substrate and a bonding layer located between the diamond and the substrate and bonding them together. The bonding layer, when inspected using ultrasound using a resolution of 50 μm, a focal length selected to inspect the bonding layer, and frequencies of 100 MHz and 30 MHz, comprises any of the following:
no area of 10 mm by 10 mm comprising more than 100 voids extending across the thickness of the bonding layer with a largest linear dimension of less than 100 μm;
no area of 10 mm by 10 mm comprising more than 5 voids extending across the thickness of the bonding layer with a largest linear dimension of between 100 μm and 1 mm;
no area of 10 mm by 10 mm comprising more than 1 void extending across the thickness of the bonding layer with a largest linear dimension of greater than 5 mm;
no area of 10 mm by 10 mm comprising more than 200 voids with a largest linear dimension of less than 100 μm, wherein said voids do not extend across the thickness of the bonding layer;
no area of 10 mm by 10 mm comprising more than 10 voids with a largest linear dimension of between than 100 μm and 2 mm, wherein said voids do not extend across the thickness of the bonding layer; and
no area of 10 mm by 10 mm comprising more than 2 voids with a largest linear dimension of greater than 2 mm, wherein said voids do not extend across the thickness of the bonding layer.

As an option, the bonding layer comprises any of the following:
no area of 10 mm by 10 mm comprising more than 50, 40 or 10 voids extending across the thickness of the bonding layer with a largest linear dimension of less than 100 μm;
no area of 10 mm by 10 mm comprising more than 3 voids extending across the thickness of the bonding layer with a largest linear dimension of between 100 μm and 1 mm;
no area of 10 mm by 10 mm comprising more than 100, 50 or 20 voids with a largest linear dimension of less than 100 μm, wherein said voids do not extend across the thickness of the bonding layer;
no area of 10 mm by 10 mm comprising more than 5 voids with a largest linear dimension of between than 100 μm and 2 mm, wherein said voids do not extend across the thickness of the bonding layer; and
no area of 10 mm by 10 mm comprising more than 1 void with a largest linear dimension of greater than 2 mm, wherein said voids do not extend across the thickness of the bonding layer.

The bonded diamond assembly is optionally capable of holding a current density selected from any of 200 to 40,000 Am⁻², 1000 to 30,000 Am⁻², 10,000 to Am⁻².

The bonding layer, when inspected using ultrasound using a resolution of 50 μm, a focal length selected to inspect the bonding layer, and frequencies of 100 MHz and 30 MHz, optionally comprises any of the following:
no area of 10 mm by 10 mm comprising more than 100 particulate impurities having a largest linear dimension of less than 100 μm;
no area of 10 mm by 10 mm comprising more than 5 particulate impurities having a largest linear dimension of between 100 μm and 1 mm; and
no area of 10 mm by 10 mm comprising more than 1 particulate impurity having a largest linear dimension of between 1 mm and 5 mm.

As an option, a surface of the polycrystalline diamond wafer has an average flatness selected from any of no more than 40 μm, no more than 30 μm, no more than 20 μm and no more than 10 μm.

The bonded diamond assembly is optionally capable of withstanding a mechanical load at least 5 bar without cracking the polycrystalline diamond wafer.

As an option, the polycrystalline wafer is electrically conducting, the substrate is electrically conducting, and the bonding layer is electrically conductive. As a further option, the polycrystalline diamond wafer comprises boron doped diamond. As a further option, the electrically conductive adhesive layer is an electrically conductive epoxy resin. As a further option, the electrically conductive epoxy resin is formed from any of a two-part epoxy resin and a preformed epoxy resin sheet. Such a diamond assembly is optionally configured to be used a temperature selected from any of greater than 20° C., greater than 40° C., and greater than 80° C.

The polycrystalline diamond wafer optionally has an average thickness selected from any of 200 μm to 2 mm, 300 μm to 1.5 mm, and 500 μm to 1 mm.

The bonding layer optionally has an average thickness selected from any of 10 μm to 250 μm, 15 μm to 150 μm, and 20 μm to 100 μm.

The polycrystalline diamond wafer optionally has a largest linear dimension selected from any of at least 40 mm, at least 44 mm, at least 50 mm, at least 75 mm and at least 100 mm.

As an option, the diamond assembly is configured to hold a current density of at least at least 15,000, at least 20,000, at least 25,000 and at least 30,000 Am⁻².

The substrate optionally comprises a metal, for example any of titanium, tungsten, iron, nickel, molybdenum and alloys thereof.

The diamond assembly optionally comprises a metallized layer on a surface of the polycrystalline diamond wafer located between the surface of the polycrystalline diamond wafer and the bonding layer.

According to a second aspect, there is provided a method of forming the bonded diamond assembly as described above in the first aspect. The method includes:
providing a polycrystalline diamond wafer having a largest linear dimension of between 25 mm and 200 mm;
providing a substrate;
bonding the substrate and the polycrystalline CVD diamond wafer via a bonding layer disposed between the polycrystalline diamond wafer and the substrate.

As an option, the bonding layer comprises an epoxy resin, and the step of bonding the substrate and the polycrystalline CVD diamond wafer via the bonding layer comprises applying elevated pressure and elevated temperature to the diamond assembly.

The elevated pressure is optionally selected from a range of 20 kNm⁻² to 3 MNm⁻². The elevated temperature is optionally selected from 25° C. to 150° C. The elevated pressure and temperature is optionally applied for between 1 and 15 hours.

As an option, the elevated temperature is achieved by applying heat to any of the polycrystalline CVD diamond wafer and the substrate.

The method optionally further comprises applying a further heat treatment to the diamond assembly at a temperature in a range of 80° C. to 200° C. and a time of at least 1 hour.

According to a third aspect, there is provided apparatus for of forming the diamond assembly as described above in the first aspect, the apparatus comprising;
a press configured to provide an elevated pressure to components of the diamond assembly, the elevated pressure selected from a range of 20 kNm⁻² to 3 MNm⁻² to an area having a largest linear dimension of between 25 mm and 200 mm;
a heater configured to provide an elevated temperature in a range of 25° C. to 150° C. to components of the diamond assembly; and
a controller comprising a timer, the controller configured to control the pressure and temperature.

According to a fourth aspect, there is provided electrochemical cell for treating a fluid, the electrochemical cell comprising at least two opposing electrodes defining a flow path for the fluid between the electrodes, where at least one of the electrodes is formed of the diamond assembly described above using electrically conductive diamond, and drive circuitry configured to apply a potential across the electrodes such that a current flows between the electrodes when the fluid is flowed through the flow path between the electrodes.

According to a fourth aspect, there is provided a bonded diamond assembly comprising a polycrystalline diamond wafer having a largest linear dimension of between 25 mm and 200 mm, a substrate, a bonding layer located between the diamond and the substrate and bonding them together, and wherein a first surface of the polycrystalline diamond wafer opposite a second surface in contact with the bonding layer has an average flatness of no more than 40 μm. As an option, the average flatness is selected from any of no more than 30 μm, no more than 20 μm and no more than 10 μm.

According to a fifth aspect, there is provided a bonded diamond assembly described above in the fourth aspect, wherein the bonding layer, when inspected using ultrasound using a resolution of 50 μm, a focal length selected to inspect the bonding layer, and frequencies of 100 MHz and 30 MHz, comprises any of the following:
no area of 10 mm by 10 mm comprising more than 100 voids extending across the thickness of the bonding layer with a largest linear dimension of less than 100 μm;
no area of 10 mm by 10 mm comprising more than 5 voids extending across the thickness of the bonding layer with a largest linear dimension of between 100 μm and 1 mm;
no area of 10 mm by 10 mm comprising more than 1 void extending across the thickness of the bonding layer with a largest linear dimension of greater than 5 mm;
no area of 10 mm by 10 mm comprising more than 200 voids with a largest linear dimension of less than 100 μm, wherein said voids do not extend across the thickness of the bonding layer;
no area of 10 mm by 10 mm comprising more than 10 voids with a largest linear dimension of between than 100 μm and 2 mm, wherein said voids do not extend across the thickness of the bonding layer; and
no area of 10 mm by 10 mm comprising more than 2 voids with a largest linear dimension of greater than 2 mm, wherein said voids do not extend across the thickness of the bonding layer.

### BRIEF DESCRIPTION OF DRAWINGS

Non-limiting embodiments will now be described by way of example and with reference to the accompanying drawings in which:

FIG. 1 is a flow diagram showing exemplary steps for preparing a diamond assembly;

FIG. 2 illustrates the components of the bonded assembly prior to bonding;

FIG. 3 illustrates schematically exemplary apparatus for bonding the unbonded assembly;

FIG. 4 illustrates schematically a cross-section side elevation view through a bonded diamond assembly;

FIGS. 5 to 8 are Confocal Scanning Acoustic Microscope (CSAM) images of exemplary bonded diamond assemblies;

FIG. 9 shows two CSAM images illustrating how voids can lead to cracking; and

FIG. 10 illustrates schematically an exemplary electrochemical cell for treating a fluid.

### DETAILED DESCRIPTION

As described above, voids in a bonding layer between a polycrystalline diamond wafer and a substrate can lead to cracking of the diamond assembly. When a bonding layer is formed from a two-part epoxy resin, mixing of the two parts and application of the two parts to a surface can introduce voids. The larger the area to be covered, the greater the problem with voids. Furthermore, voids can migrate to the edges of a circular assembly, leading to cracking and delamination of the layers towards the edges rather than at the centre of the assembly.

Diamond assemblies of this type use polycrystalline CVD diamond, which is opaque or translucent, and so voids and impurities can be difficult to detect. However, they can be detected and assessed non-destructively using techniques such as a scanning acoustic microscopy.

It has been found that certain amounts of voids can be tolerated in most applications, and that general techniques such as overpressure during application of the bonding layer and high cleanliness can be helpful to reduce the amount of voids in the bonding layer between the polycrystalline diamond and the substrate.

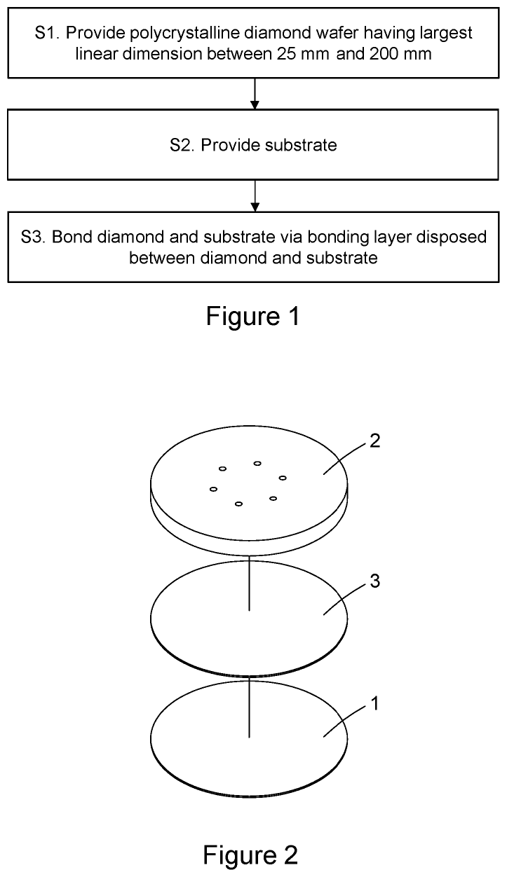

FIG. 1 illustrates the steps in forming a diamond assembly. The following numbering corresponds to that of FIG. 1.

S1. A grown freestanding polycrystalline diamond wafer having a largest linear dimension of between 25 mm and 200 mm is provided. For a disc wafer, the largest linear dimension is the diameter of the disc. In some embodiments, the largest linear dimension is at least 40 mm, at least 44 mm, at least 50 mm, at least 75 mm and at least 100 mm. The wafer is processed (for example by laser trimming) to a desired size. It may be checked for cracks, pits and edge chips by a visual inspection or other suitable techniques such as dye penetration. Note also that one surface of the wafer may be metallized to improve adhesion to the bonding layer and provide ohmic conduction to the diamond. Metallization may be done using metals such as platinum, gold, titanium, chromium, molybdenum, tungsten or alloys thereof, such as chromium/gold or platinum silver. Carbide forming metals may also be used for metallization. The total metal thickness is typically less than 50 μm, less than 25 μm, less than 15 μm, less than 8 μm, less than 3 μm or less than 1 μm.

Typical thickness for the wafer range from 50 μm to above 1 mm, depending on the application. For example, a wafer thickness may be greater than 50 μm, greater than 100 μm, greater than 200 μm, greater than 300 μm, greater than 500 μm or greater than 750 μm. Typically the wafer thickness is no more than 2 mm, or no more than 1 mm, depending on the final use.

S2. A suitable substrate to which the wafer is to be attached is provided. Exemplary materials for the substrate include titanium, tungsten, iron, nickel, chromium, aluminium, silicon, silicon carbide, niobium, molybdenum, vanadium, and alloys thereof (such as Invar). Prior to bonding, the substrate is processed to achieve a flatness of preferably <50%, even more preferably <30% even more preferably <20%, even more preferably <10% of the bond layer thickness using a range of techniques including mechanical lapping, turning, etching grinding, then cleaned and thoroughly de-greased.

S3. A bonding layer is located between the cleaned surface of the substrate and the diamond wafer, and the diamond and substrate are bonded together. The bonding layer is selected to have the required properties for the end application.

For example, where a suitable bonding layer is required to be electrically conductive, it has a resistivity of <0.001 Ωcm and has thermal conductivity >1 W m⁻¹ K⁻¹ with bondline thicknesses of less than 0.250 mm, ideally less than 0.1 mm. The surfaces of the two parts may be treated to enhance adhesion, by lowering surface energy via acid cleaning, plasma etching and depositing thin film metal, e.g. gold coatings to enhance the shear strength of the bondline.

Suitable bonding layers include silver and graphite loaded adhesives such as; polyester and epoxy resins, thermosetting, thermoplastic and adhesives. Where the diamond is BDD and the end use requires conduction of electricity, an electrically conductive bonding layer is used. It will be apparent that minimizing voids in the bonding layer is critical to ensure electrical conduction Pre-impregnated adhesive sheet materials are often used to give precise control of bondline thickness, and are available from a range of commercial sources.

Low viscosity two-part epoxy resins are also suitable, although it is harder to precisely control the bondline thickness, while minimising voids.

FIG. 2 shows an assembly prior to bonding. The polycrystalline diamond wafer 1 and a substrate 2 are provided and the bonding layer 3 is located between them.

Where a pre-impregnated epoxy bonding layer is used, the unbonded assembly is cured using elevated temperature and/or the application of pressure. An example of a suitable epoxy bonding layer is Loctite™ Ablestik CF 3350. Typical pressures are in a range of 20 kNm⁻² to 3 MNm⁻². The applied pressures can be significantly higher than those required to cure the epoxy, as this can assist in reducing the number of voids in the bonding layer 3. The curing temperature is typically in a range from 50° C. to 150° C., depending on the epoxy used and desired curing time. Note that in some applications, the bonded diamond assembly may be used at temperatures greater than 20° C., greater than 40° C. or greater than 80° C. The elevated pressure and temperature is typically applied for between 1 and 15 hours, again depending on the epoxy used. Elevated temperature may be achieved by applying heat to the polycrystalline CVD diamond wafer and/or the substrate. After bonding, a further heat treatment may be applied to the diamond assembly at a temperature in a range of 80° C. to 200° C. and a time of at least 1 hour. A further consideration is the final operating temperature of the component in use, in order to minimise the stresses from CTE mismatch the ideal curing temperature is close to the operating temperature. Different adhesive options can be used to match from room temperature, high viscosity two part resins to 150° C. pre-impregnated high temperature adhesive sheets.

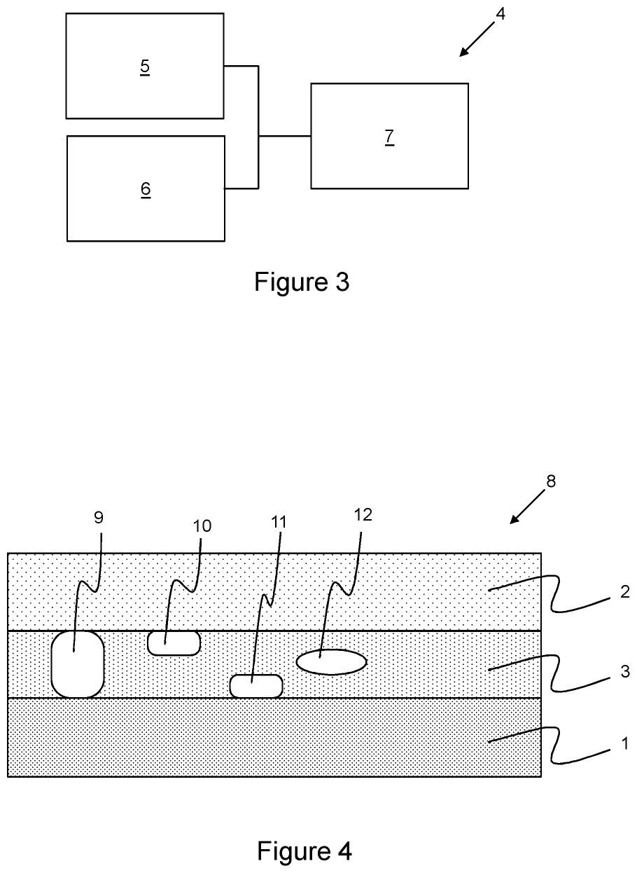

FIG. 3 illustrates schematically exemplary apparatus 4 for bonding the unbonded assembly. The apparatus 4 comprises a press 5 configured to provide an elevated pressure to components of the diamond assembly, the elevated pressure selected from a range of 20 kNm⁻² to 3 MNm⁻² to an area having a largest linear dimension of between 25 mm and 200 mm. A heater 6 is also provided, configured to provide an elevated temperature in a range of 25° C. to 150° C. to components of the diamond assembly A controller 7 is provided that includes a timer. The controller 7 is configured to control the pressure and temperature.

FIG. 4 illustrates schematically a cross-section side elevation view (not to scale) through a bonded diamond assembly 8, showing a polycrystalline diamond wafer 1, a substrate 2, and a bonding layer 3 binding the substrate 2 and the polycrystalline diamond layer together. Exemplary voids are also shown in the bonding layer 3.

Some voids, defined as gaps between either the substrate and the bond layer or visa-versa 9 extend across the thickness of the bonding layer such that they contact both the substrate 2 and the polycrystalline diamond wafer 1. Some voids 10 contact the substrate 2 but do not extend across the thickness of the bonding layer 3. Some voids 11 contact the polycrystalline diamond wafer 1 but do not extend across the thickness of the bonding layer, so do not contact the substrate 2. Some voids 12 do not extend across the thickness of the bonding layer 3 and do not contact either the polycrystalline diamond wafer 1 or the substrate 2.

Particulates, defined as 0.01-0.1 mm diameter impurities in the bonding layer 3 can be thought of in similar ways to the voids 9, 10, 11, 12.

As polycrystalline diamond and the substrate may be opaque, it is difficult to visually inspect a bonded diamond assembly in order to look at the presence of voids or particulates. A more suitable technique is to use a C-Mode Scanning Acoustic Microscope (CSAM). In the examples below, a Nordson Sonoscan D9600 CSAM was used with Acoustic Micro Imaging (AMI).

The CSAM was focused through the polycrystalline diamond wafer side rather than the substrate side, using a resolution of 50 μm and a focal length suitable to image the binding layer. Each sample was measured using two frequencies, 100 MHz and 30 MHz in order to provide more information. Broadly higher frequency, 100 MHz imaging provides greater resolution for defects such as particulates, while lower frequency imaging provides greater contrast between voids and the fully bonded regions of the bond line.

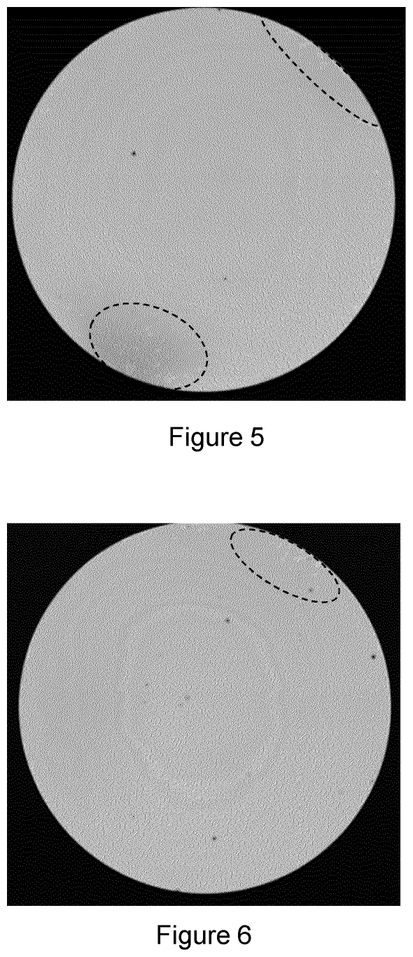

FIGS. 5 to 9 are CSAM images of bonded diamond assemblies made using titanium substrates having thickness between 11.8 and 12.2 mm and machined to a flatness of between 1 to 6 μm. BDD polycrystalline diamond wafers had thicknesses between 350 and 850 μm. Before bonding to form the assembly, the polycrystalline wafers had measured bowing of between 150 and 600 μm. The substrate and the polycrystalline diamond wafers in this example were in the form of discs with a diameter of 138 mm. An electrically conducting two part epoxy resin was used to bond the substrates to the polycrystalline diamond wafers. The bonding layer was between 30 and 100 μm thick. Once the BDD polycrystalline diamond wafers had been bonded to the substrates, the surface of the BDD wafer opposite to the surface adjacent to the bonding layer had measured flatnesses of 9 to 40 μm.

The CSAM image in FIG. 5 shows voids towards the edges of the bonded diamond assembly, highlighted by the dashed lines. This level of voids is acceptable as it did not lead to cracking. Similarly, the CSAM image of FIG. 6 shows an acceptable level of voids (highlighted by the dashed line).

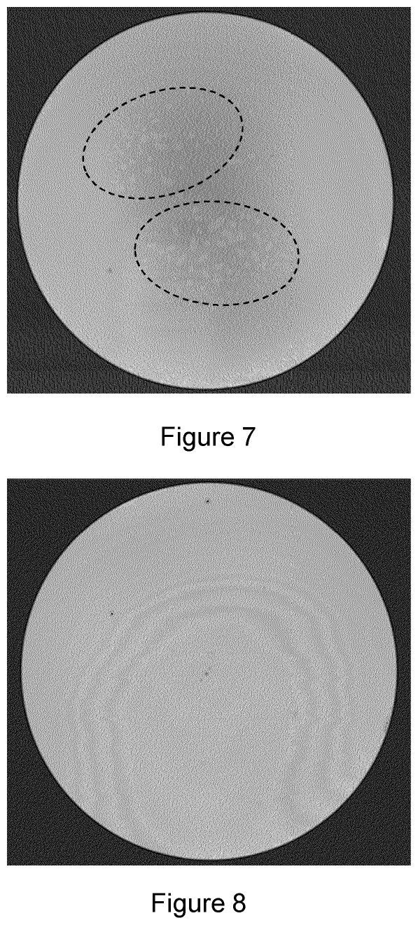

The CSAM image in FIG. 7 shows a very high level of voids, that would be considered to be unacceptable. The main areas of voids are highlighted by the dashed lines and in this case are mostly towards the centre of the bonded diamond assembly, although some voids are observable towards the edges of the assembly.

The CSAM in FIG. 8 shows no appreciable voids, and is illustrative of a very good contact between the bonding layer 3 and the polycrystalline diamond wafer 1 and the substrate 2.

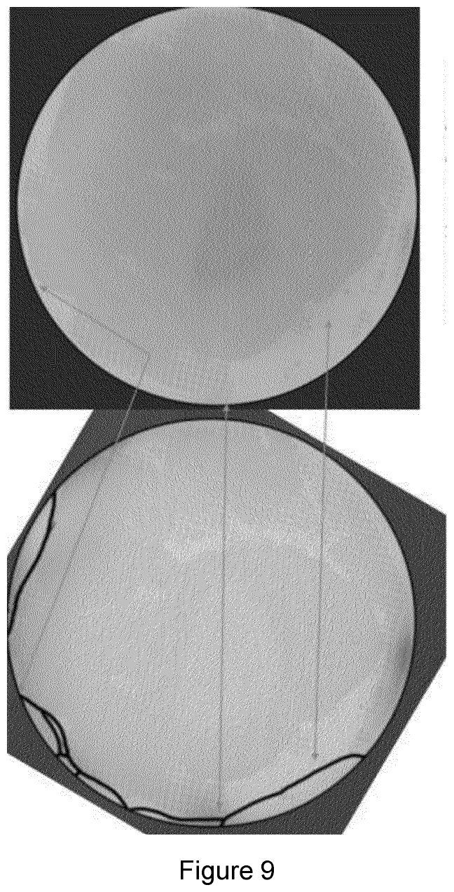

FIG. 9 shows appreciable cracks towards the edge of the diamond wafer layer 1, which correspond to areas having the highest number of voids. This emphasizes the importance of keeping the number and size of voids in the bonding layer within levels acceptable to avoid cracking, particularly when under load.

Acceptable numbers and sizes of voids have been found to be as follows: The bonding layer 3 must have no area of 10 mm by 10 mm comprising more than 100, 50, 40 or 10 voids extending across the thickness of the bonding layer with a largest linear dimension of less than 100 μm. The bonding layer 3 must have no area of 10 mm by mm comprising more than 5 or 3 voids extending across the thickness of the bonding layer with a largest linear dimension of between 100 μm and 1 mm. The bonding layer 3 must have no area of 10 mm by 10 mm comprising more than 1 void extending across the thickness of the bonding layer with a largest linear dimension of greater than 5 mm. The bonding layer 3 must have no area of 10 mm by 10 mm comprising more than 200, 100, 50 or 20 voids with a largest linear dimension of less than 100 μm, wherein said voids do not extend across the thickness of the bonding layer. The bonding layer 3 must have no area of 10 mm by 10 mm comprising more than 10 or 5 voids with a largest linear dimension of between than 100 μm and 2 mm, wherein said voids do not extend across the thickness of the bonding layer. The bonding layer 3 must have no area of 10 mm by 10 mm comprising more than 2 or 1 voids with a largest linear dimension of greater than 2 mm, wherein said voids do not extend across the thickness of the bonding layer. These figures are determined using the CSAM inspection technique described above. The minimum void size is at least 1 μm, at least 5μ or at least 10 μm.

Furthermore, particulate impurities in the bonding layer 3 must also be kept within acceptable levels. The bonding layer 3 must have no area of 10 mm by 10 mm comprising more than 100, 50, 20 or 10 particulate impurities having a largest linear dimension of less than 100 μm. The bonding layer 3 must have no area of 10 mm by 10 mm comprising more than 5 3 or 1 particulate impurities having a largest linear dimension of between 100 μm and 1 mm. The bonding layer 3 must have no area of 10 mm by 10 mm comprising more than 1 particulate impurity having a largest linear dimension of between 1 mm and 5 mm.

Whether a void extends all the way through the thickness of the bonding layer, or just partially through the thickness of the bonding layer, can be differentiated using C-SAM. Defects and voids can be seen in 100 MHz C-SAM, while voids have better contrast in 30 MHz C-SAM.

In addition to reducing cracking, other advantages of keeping voids and particulate in the bonding layer to within acceptable levels include allowing BDD assemblies to hold higher and more uniform current densities, and to allow heat spreaders to more uniformly conduct heat.

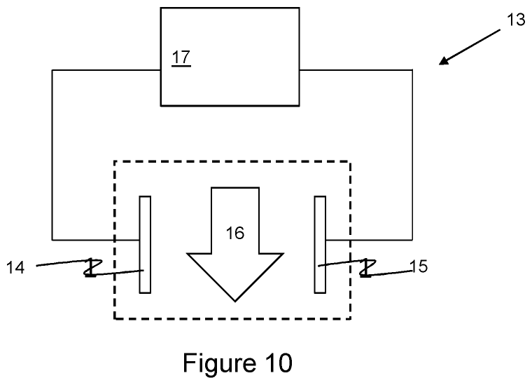

An electrochemical cell, as illustrated in FIG. 10, was prepared. The electrochemical cell 13 comprised a first electrode 14 and a second electrode 15, each electrode 14, 15 formed from a BDD bonded assembly. A fluid path 16 allowed fluid to pass between the electrodes 14, 15. Drive circuitry 17 was provided to apply a potential across the electrodes 14, 15 such that a current flows between the electrodes when the fluid is flowed through the flow path between the electrodes. The electrodes 14, 15 had an active area with a diameter of 128 mm.

Current densities of between 200 and 40,000 Am⁻² can be held by the electrodes. Table 1 illustrates the current, current density and voltage of an exemplary cell.

TABLE 1
Exemplary current, current density and voltage

| Current/A | Current Density/Am⁻² | Voltage per cell/V |
|---|---|---|
| 10 | 778 | 1 |
| 40 | 3109 | 3 |
| 70 | 5440 | 5 |
| 100 | 7772 | 7 |
| 130 | 10103 | 10 |
| 160 | 12434 | 12 |
| 190 | 14766 | 14 |
| 220 | 17097 | 16 |
| 250 | 19429 | 18 |
| 280 | 21760 | 20 |
| 310 | 24091 | 22 |
| 340 | 26423 | 24 |
| 370 | 28754 | 26 |
| 400 | 31085 | 28 |

The invention as defined in the appended claims has been shown and described with reference to the embodiments above. However, it will be understood by those skilled in the art that various changes in form and detail may be made without departing from the scope of the invention as defined by the appended claims, and while exemplary methods have been described, it may be that other methods may be used to obtain the diamond material of the appended claims.

1. A bonded diamond assembly comprising:
a polycrystalline diamond wafer having a largest linear dimension of between 25 mm and 200 mm;
a substrate;
a bonding layer located between the diamond and the substrate and bonding them together;
wherein the bonding layer, when inspected using ultrasound using a resolution of 50 μm, a focal length selected to inspect the bonding layer, and frequencies of 100 MHz and 30 MHz, comprises any of the following:
no area of 10 mm by 10 mm comprising more than 100 voids extending across the thickness of the bonding layer with a largest linear dimension of less than 100 μm;
no area of 10 mm by 10 mm comprising more than 5 voids extending across the thickness of the bonding layer with a largest linear dimension of between 100 μm and 1 mm;
no area of 10 mm by 10 mm comprising more than 1 void extending across the thickness of the bonding layer with a largest linear dimension of greater than 5 mm;
no area of 10 mm by 10 mm comprising more than 200 voids with a largest linear dimension of less than 100 μm, wherein said voids do not extend across the thickness of the bonding layer;
no area of 10 mm by 10 mm comprising more than 10 voids with a largest linear dimension of between than 100 μm and 2 mm, wherein said voids do not extend across the thickness of the bonding layer; and
no area of 10 mm by 10 mm comprising more than 2 voids with a largest linear dimension of greater than 2 mm, wherein said voids do not extend across the thickness of the bonding layer.

2. (canceled)

3. (canceled)

4. The bonded diamond assembly according to claim 1, wherein the bonding layer, when inspected using ultrasound using a resolution of 50 μm, a focal length selected to inspect the bonding layer, and frequencies of 100 MHz and 30 MHz, comprises any of the following:
no area of 10 mm by 10 mm comprising more than 100 particulate impurities having a largest linear dimension of less than 100 μm;
no area of 10 mm by 10 mm comprising more than 5 particulate impurities having a largest linear dimension of between 100 μm and 1 mm; and
no area of 10 mm by 10 mm comprising more than 1 particulate impurity having a largest linear dimension of between 1 mm and 5 mm.

5. The bonded diamond assembly according to claim 1, wherein a surface of the polycrystalline diamond wafer has an average flatness selected from any of no more than 40 μm, no more than 30 μm, no more than 20 μm and no more than 10 μm.

6. (canceled)

7. The bonded diamond assembly according to claim 1, wherein:
the polycrystalline wafer is electrically conducting;
the substrate is electrically conducting; and
the bonding layer is electrically conductive.

8. The diamond assembly according to claim 7, wherein the polycrystalline diamond wafer comprises boron doped diamond.

9. The diamond assembly according to claim 7, wherein the electrically conductive adhesive layer is an electrically conductive epoxy resin.

10. The diamond assembly according to claim 9, wherein the electrically conductive epoxy resin is formed from any of a two-part epoxy resin and a preformed epoxy resin sheet.

11. (canceled)

12. The diamond assembly according to claim 1, wherein the polycrystalline diamond wafer has an average thickness selected from any of 200 μm to 2 mm, 300 μm to 1.5 mm, and 500 μm to 1 mm.

13. The diamond assembly according to claim 1, wherein the bonding layer has an average thickness selected from any of 10 μm to 250 μm, 15 μm to 150 μm, and 20 μm to 100 μm.

14. The diamond assembly according to claim 1, wherein the polycrystalline diamond wafer has a largest linear dimension selected from any of at least 40 mm, at least 44 mm, at least 50 mm, at least 75 mm and at least 100 mm.

15. (canceled)

16. The diamond assembly according to claim 1, wherein the substrate comprises a metal.

17. The diamond assembly according to claim 16, wherein the metal is selected from any of titanium, tungsten, iron, nickel, molybdenum and alloys thereof.

18. (canceled)

19. A method of forming the diamond assembly according to claim 1, the method comprising:
providing a polycrystalline diamond wafer having a largest linear dimension of between 25 mm and 200 mm;
providing a substrate;
bonding the substrate and the polycrystalline CVD diamond wafer via a bonding layer disposed between the polycrystalline diamond wafer and the substrate.

20. The method according to claim 19, wherein the bonding layer comprises an epoxy resin, and the step of bonding the substrate and the polycrystalline CVD diamond wafer via the bonding layer comprises applying elevated pressure and elevated temperature to the diamond assembly.

21. The method according to claim 20, wherein the elevated pressure is selected from a range of 20 kNm⁻² to 3 MNm⁻².

22. The method according to claim 20, wherein the elevated temperature is selected from 25° C. to 150° C.

23. (canceled)

24. (canceled)

25. (canceled)

26. (canceled)

27. An electrochemical cell for treating a fluid, the electrochemical cell comprising:
at least two opposing electrodes defining a flow path for the fluid between the electrodes, where at least one of the electrodes is formed of the diamond assembly according to claim 7; and
drive circuitry configured to apply a potential across the electrodes such that a current flows between the electrodes when the fluid is flowed through the flow path between the electrodes.

28. A bonded diamond assembly comprising:
a polycrystalline diamond wafer having a largest linear dimension of between 25 mm and 200 mm;
a substrate;
a bonding layer located between the diamond and the substrate and bonding them together;
and wherein a first surface of the polycrystalline diamond wafer opposite a second surface in contact with the bonding layer has an average flatness of no more than 40 μm.

29. (canceled)

30. (canceled)

31. (canceled)
